(19) United States
(12) Patent Application Publication
(10) Pub. No.: US 2025/0192730 A1
(43) Pub. Date: Jun. 12, 2025

(54) METHODS AND DEVICES FOR ADAPTIVE POWER AMPLIFIER PRE-DISTORTION

(71) Applicants: Huawei Technologies Canada Co., Ltd., Ottawa (CA); The University of Western Ontario, London (CA)

(72) Inventors: Pengyi JIA, London (CA); Jiazhi CHEN, London (CA); Xianbin WANG, London (CA); Ming JIAN, Kanata (CA); Peyman NESHAASTEGARAN, Stittsville (CA)

(21) Appl. No.: 18/612,486

(22) Filed: Mar. 21, 2024

Related U.S. Application Data
(60) Provisional application No. 63/607,676, filed on Dec. 8, 2023.

(51) Int. Cl. H03F 1/32; H03F 3/24; H04B 1/04

(52) U.S. Cl. CPC H03F 1/3247; H03F 1/3258; H03F 3/24; H04B 1/0475; H04B 2001/0425

(57) ABSTRACT

Methods and systems and devices for adaptively updating digital predistortion parameters for a power amplifier distortion model in a wireless communications network base station. The updated parameters are determined by a computing device separate from the base station. The base station monitors one or more operating conditions. When an operating condition differs from a stored operating condition by more than a threshold amount, the base station requests a parameter update from the computing device and receives a scheduled time to submit signals. Power amplifier input and output signals are provided to the computing device at the schedule time and the computing device determines the updated power amplifier distortion model and, consequently, the updated predistortion parameters, which it provides to the base station.

### CROSS-REFERENCE TO RELATED APPLICATIONS

The present application claims priority to U.S. provisional patent application No. 63/607,676, filed Dec. 8, 2023, the contents of which are hereby incorporated by reference.

### FIELD

The present application relates to power amplifiers and, in particular to methods and devices for adaptive adjustments to pre-distortion of the input signal to a power amplifier.

### BACKGROUND

In wireless communications networks, base stations include power amplifiers to amplify RF signals for transmission. The power amplifiers often introduce non-linearities in the amplified RF signal. Accordingly, base stations typically include pre-distortion to modify the input signal so as to offset the expected distortion caused by the power amplifier.

The non-linear distortion of the power amplifier can change with time and under different operating conditions. Accordingly, it would be advantageous to have a computationally efficient and low-cost mechanism for updating the pre-distortion to account for changes in the non-linear distortion of the power amplifier.

### BRIEF DESCRIPTION OF THE DRAWINGS

Reference will now be made, by way of example, to the accompanying drawings in which:

FIG. 1 shows, in block diagram form, a simplified example of a mobile communications network;

FIG. 2 shows, in flowchart form, one simplified example method for initial configuration of base stations in a mobile communications network;

FIG. 3 shows, in flowchart form, a simplified example method for updating pre-distortion values in a base station using a training device;

FIG. 4 shows, one simplified example method for updating DPD parameters for a plurality of base stations using two or more training devices;

FIG. 5 shows experimental results from use of a multi-factor memory polynomial power amplifier nonlinearity model, in terms of normalized mean squared error for a range of different scenarios;

FIG. 6 shows modelled results from three specific training approaches, including remote, on-device, and the proposed interactive offloading approach;

FIG. 7 shows one simplified example of a computing device; and

FIG. 8 shows a simplified organization of software components stored in memory of an example computing device.

Like reference numerals are used in the drawings to denote like elements and features.

### DETAILED DESCRIPTION

In one aspect, the present application describes a computing device for use in a wireless network, the wireless network including a plurality of base stations. The computing device may include a controller configured to receive a request for distortion model update from one of the base stations; a communications subsystem configured to, in response to the request, send a message to the base station and to receive, during a time window, a power amplifier input signal and a power amplifier output signal from said one of the base stations; and a digital signal processor to generate an updated set of parameters for a predistortion model using the power amplifier input signal and the power amplifier output signal. The communications subsystem may be further configured to transmit the updated set of parameters to said one of the base stations in response to the request.

In some implementations, the request for distortion model update includes data regarding an operating condition that triggered transmission of the request for distortion model update. In some cases, the data regarding the operating condition includes a measurement at the base station of one of temperature, voltage, power, or operating bandwidth.

In some implementations, wherein the power amplifier output signal is an analog waveform. In some cases, the analog waveform is an RF waveform at a transmission frequency.

In some implementations, the message sent to the base station includes data specifying the time window, and wherein the time window begins at a future time.

In some implementations, the controller is configured to determine the time window in part based upon whether other requests for distortion model update have been received from other base stations, computational workload at the computing device, or severity of variation in the operating condition.

In some implementations, the request for distortion model update, the message, the power amplifier input signal, and the power amplifier output signal are communicated over fronthaul or backhaul network links.

In another aspect, the present application describes a base station for wireless communications that includes an RF chain that receives an input signal and produces a power amplifier output signal to drive an antenna array, the RF chain including a predistortion model, a digital-to-analog converter, an up-converter, and a power amplifier; a sensor monitoring an operating condition at the base station; and a controller for receiving a signal from the sensor. The controller may be configured to, in response to determining that the operating condition varies from a previously determined operating condition, transmit a request for distortion model update to a computing device; receive a response and, based on the response, during a time window, transmit a power amplifier input signal and the power amplifier output signal to the computing device; receive, from the computing device, an updated set of parameters for the predistortion model; and update the predistortion model using the updated set of parameters.

In some implementations, the controller is configured to determine that the operating condition varies from a previously determined operating condition by determining that a value measured by the sensor differs from the previously determined operating condition by more than a threshold amount.

In yet another aspect, the present application describes a method of adaptively updating a predistortion model for a power amplifier for a base station, the method including receiving at a remote computing device, from the base station, a request for distortion model update; in response to the request, sending a message to the base station and receiving, during a time window, a power amplifier input signal and a power amplifier output signal from the base station; generating an updated set of parameters for the predistortion model using the power amplifier input signal and the power amplifier output signal; and transmitting the updated set of parameters for the predistortion model to the base station to be used in updating the predistortion model.

In some implementations, receiving the request for distortion model update includes receiving data regarding an operating condition that triggered transmission of the request for distortion model update. In some cases, wherein the data regarding the operating condition includes a measurement at the base station of one of temperature, voltage, power, or operating bandwidth.

In some implementations, the power amplifier output signal is an analog waveform. In some cases, the analog waveform is an RF waveform at a transmission frequency.

In some implementations, the message sent to the base station includes data specifying the time window, and wherein the time window begins at a future time.

In some implementations, the method further includes determining the time window in part based upon whether other requests for distortion model update have been received from other base stations, computational workload at the computing device, or severity of the operating condition.

In some implementations, the request for distortion model update, the message, the power amplifier input signal, and the power amplifier output signal are communicated over fronthaul or backhaul network links.

In another aspect, the present application describes a method of adaptively updating a predistortion model for a power amplifier in a base station, the base station including an RF chain that receives an input signal and produces a power amplifier output signal to drive an antenna array, the RF chain including a predistortion model, a digital-to-analog converter, an up-converter, and a power amplifier. The method may include monitoring an operating condition using a sensor; in response to determining that the operating condition varies from a previously determined operating condition, transmitting a request for distortion model update to a computing device; receive a response and, based on the response, during a time window, transmitting a power amplifier input signal and the power amplifier output signal to the computing device; receiving, from the computing device, an updated set of parameters for the predistortion model; and updating the predistortion model using the update set of parameters.

In some implementations, determining that the operating condition varies from a previously determined operating condition includes determining that a value measured by the sensor differs from the previously determined operating condition by more than a threshold amount.

In a further aspect, the present application describes a computing device that includes a processor and memory storing processor-executable instructions that, when executed by the processor, are to cause the processor to carry out one or more of the methods described herein.

According to another aspect, the present application discloses a non-transitory computer readable storage medium containing computer-executable instructions which, when executed, configure a processor to carry one or more of the methods described herein.

Other aspects and features of the present application will be understood by those of ordinary skill in the art from a review of the following description of examples in conjunction with the accompanying figures.

In the present application, the phrase “at least one of . . . or . . . ” is intended to cover any one or more of the listed elements, including any one of the listed elements alone, any sub-combination, or all of the elements, without necessarily excluding any additional elements, and without necessarily requiring all of the elements. The term “and/or” is intended to indicate that either of the two elements may be included or both of the elements may be included.

In wireless communications, base stations provide the wireless link from the network to a plurality of user devices in the area near the base station. A base station (BS) typically includes an antenna array connected to one or more RF transceivers. In simple terms, the transceivers may receive a baseband digital input, which is then converted to analog and amplified by a power amplifier to excite the antenna array and propagate the RF signal. As wireless communications have evolved from 3G to 4G, LTE, 5G and, soon, 6G, the size of cells has shrunk, the operating frequencies have increased, the bandwidth of spectrum used has increased, and the number of base stations has increased.

Each BS may typically contain a plurality of power amplifiers (PAS) each of which is operating at or near its saturation point or upper limit on capacity, which results in nonlinearities in the output RF signal. Accordingly, BSs typically also include digital predistortion (DPD) applied to the baseband signal before analog conversion and frequency up-conversion, thus ensuring improved communication performance. The DPD is intended to introduce nonlinearities in the signal that will offset the nonlinearities caused by the PA, resulting in a linearized output RF signal.

The wireless network can include both macro-cell BSs and small BSs to provide communication capability to the users within their coverage range. Macro-cell BSs are large-sized powerful BSs typically positioned to provide broad coverage and high-capacity support in urban and suburban areas. They are equipped to handle a large number of users, delivering services across wide geographical regions. Each of the macro-cell BSs will have a plurality of RF chains and a plurality of PAs with respective distortions. Small BSs are small-sized, low-powered BSs including, but not limited to, micro-cell BSs, pico-cell BSs, and femtocell BSs. They are deployed to augment the network by providing targeted coverage and capacity in densely populated areas. They support the network in handling high traffic volumes and provide service continuity in areas where macro-cell BS coverage may be inadequate. Due to the densified deployment, the power consumption and implementation cost of these BSs is an important consideration. Meanwhile, compared to macro-cell BSs, the processing power of these small BSs is insufficient or inefficient to handle computation-intensive tasks. Similar to the macro-cell BSs, each of the small BSs will also have a plurality of RF chains and a plurality of PAs with distortions.

To achieve the promised data rates and energy efficiency of 5G and 6G networks, base stations may benefit from new designs of fundamental signal processing techniques like DPD to effectively utilize the dramatically increased bandwidth. By linearizing the nonlinear distortions of BS power amplifiers, DPD can effectively mitigate co-channel interference and enhance spectral efficiency to support the data rate requirements in cellular communication systems. However, the growing complexity of 6G network architecture poses stringent requirements on the DPD design, necessitating the development of more simplified and effective distortion cancellation strategies to support various demanding vertical applications.

The accurate modeling of nonlinear distortion for all power amplifiers (PA) throughout the network would be helpful to facilitate effective DPD design, which can become extremely complex and costly in 6G networks.

DPD design typically involves development and determination of a DPD model (in one sense, a function that may be applied to the input signal prior to the PA that will offset the non-linearities that the PA introduces so as to result in an output that is linearized). The DPD model may be specific to that PA. Unfortunately, the nature of the nonlinearities of the PA may change over time. This may be due to drift of components, changes in operating conditions, or other factors that change over time. For instance, dynamic ambient temperature, operating bandwidth, and input voltage are all time-variable operating conditions that may impact PA nonlinearities.

To address changes in the PA nonlinearities over time, existing PA distortion estimation methods may conduct constant modeling of the massive PA waveform signals generated from each radio frequency (RF) chain. This may mean providing for a feedback loop in the base station, routing the PA RF output signal into a dedicated downconverter and analog-to-digital converter (ADC) for comparison and analysis by a digital signal processor with the PA input signal in order to determine real-time updated DPD parameters (e.g. function coefficients). Due to their limited processing capability, the complex and highly redundant DPD process can lead to unacceptable implementation costs for small cells. With the proliferation of small BSs over 1000 BS/km2 and the increased scale of antenna arrays within each BS in 6G networks, the implementation complexity and cost inherent to the concurrent and distributed DPD processes will explosively increase costs across the network.

Accordingly, it may be advantageous to offload the DPD parameter update analysis from individual base stations to a remote device or cloud service so as to reduce the hardware and computational burden on the base stations. For those updates to be performed, however, the remote device requires the PA input signal and the PA output signal. With a 6G network, this can be a very large data-intensive signal. Some systems attempt to address this capacity issue by digitizing and undersampling the signal, but this results in data loss and inaccuracy in the resultant modeling. Other systems attempt to address this capacity issue by way of aggressive lossy data compression, but that also results in data loss and inaccuracy. Accordingly, it would be advantageous to have an improved process and system for adaptively updating base stations that addresses at least some of these issues.

In accordance with one aspect, the present application provides a method and system and devices for adaptive DPD updates that reduces the hardware requirements in the base stations and yet addresses the communications burden for links between the base station and the remote device performing the DPD model updates.

In accordance one aspect of the present application, a computing device in the network acts as a training device for determining updated DPD parameters for one or more base stations. The computing device may be one of the base stations in some cases. In some cases, the computing device may be a cloud server, edge device, or other computing device in the network. The computing device may be referred to herein as a “training device”, although it will be appreciated that in some implementations the computing device also serves as a base station.

The computing device is connected to a plurality of base stations through network links, such as fronthaul or backhaul links of the mobile communications network. These links enable the base stations to send PA input and PA output signals in analog form to the computing device. However, to preserve bandwidth and reduce computational burden, the base stations do not send constant feedback to the computing device. Instead, the PA input and PA output signals are only sent to the computing device upon occurrence of a trigger event indicating a likely need to redetermined the DPD parameters. The computing device may assign a timeslot or scheduled window within which a particular one of the base stations is to transmit its PA input and PA output signal to the computing device for analysis. The trigger event may be one determined by the base station using one or more existing sensors or electronic measurement components in the base station. The sensors or electronic measurement components may track time-variant conditions at the base stations and, upon detecting a change in a condition greater than a threshold amount or percentage, it may determine that a DPD parameter redetermination may be needed. As examples, the condition may include ambient temperature, power supply parameters, and/or operating bandwidth. It will be appreciated that this enables the base station to avoid incorporating expensive feedback loop and signal processing architecture for determining its own DPD parameters, or for sampling and compressing the PA input and PA output signals. It is able to leverage existing sensors and, using an updated code base, determine when an operating condition has exceeded a variation threshold that triggers a DPD update process.

Upon detecting a change in an operating condition sufficient to trigger the DPD update process, the base station may send a lightweight DPD update request message or notification to the training device. The training device may, if multiple such requests have been received or if it is presently occupied with a DPD update for another base station, determine a scheduled time or window or instant during which the requesting base station may initiate transmission of its PA input and PA output signals to the training device. It returns a message to the base station specifying the scheduled time for transmission. The message may specify a start time at which the time window begins and the window length, i.e. the duration of the transmission of PA signals, or the message may specify a start time and the window length may be preset. The scheduled time may be immediate or may be at a specified time in the future.

When dealing with multiple requests, the training device may schedule DPD updates for the various requesting base stations based on first-to-arrive in some cases. In some cases, it may schedule the updates based on estimated severity or need for an update. In such cases, the request message from the base stations may include data regarding the operating condition that triggered the update request. Certain operating conditions may have a higher priority than others. The data may include the measured condition value, the threshold value, the extent to which the measured condition exceeds the threshold, and other such data to enable the training device to assess the degree of severity.

When a base station sends its PA input and PA output signals to the training device, the training device uses those signals to determine updated DPD parameters and sends those parameters to the requesting base station so that it can update its DPD model.

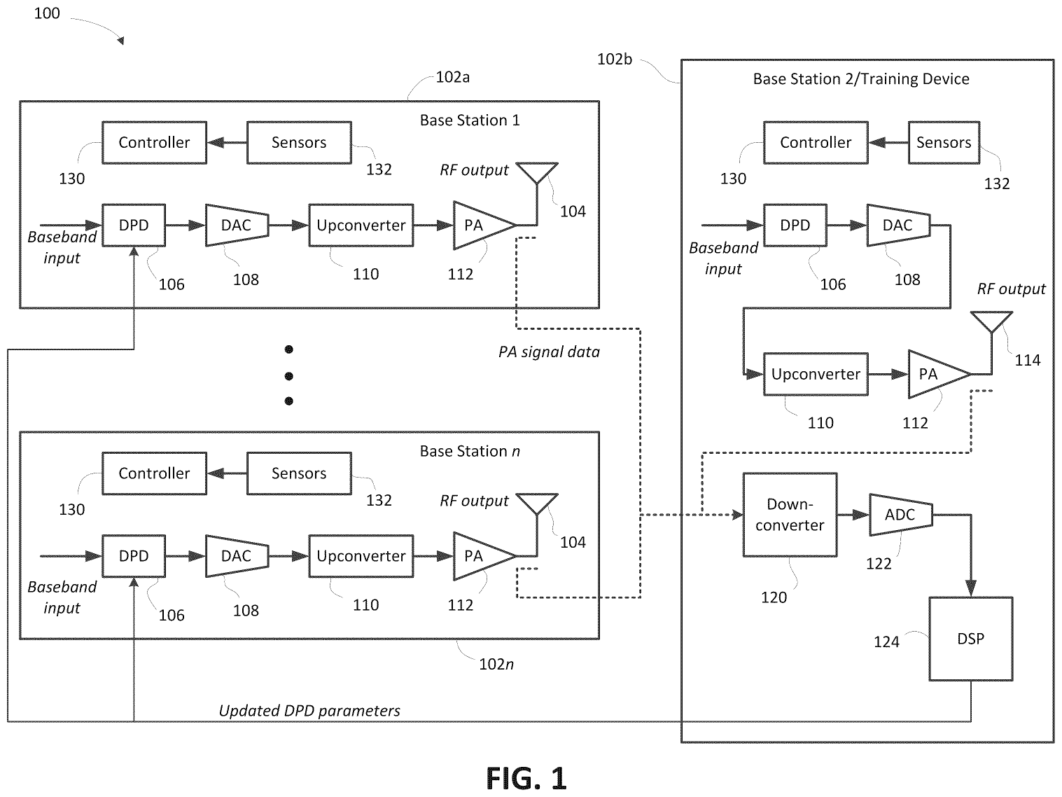

Reference is now made to FIG. 1, which shows, in block diagram form, a simplified example of a mobile communications network 100 in which one of the base stations is configured to act as a training device for other base stations. The network 100 in this example includes a plurality of base stations 102 (shown as 102a, 102b, . . . , 102n). It will be understood that, for ease of illustration, the components shown are only a small subset of the components of a typical base station and that each base station 102 would include a number of other elements. Each base station includes an RF chain that converts a baseband input digital signal to a high frequency analog RF signal for transmission via an antenna array 104. The RF chain includes a predistortion model (DPD model) 106, a digital to analog converter (DAC) 108, an up-converter 110, and an RF power amplifier (PA) 112. The DPD model 106 is designed to introduce predistortion to the baseband signal that should offset the nonlinear distortion introduced by the PA 112 when amplifying the RF signal for transmission. In this regard, the DPD model 106 utilizes a set of DPD parameters selected so as to produce the desired non-linear predistortion. As noted above, the nature of the nonlinear distortion causes by the PA 112 can vary over time, particularly with changes in operating conditions such as ambient temperature or power supply variations. In order to modify the DPD model 106 through an update to the DPD parameters, they need to be redetermined from time to time.

One of the base stations 102b serves as a training device in this example. The training device need not be a base station in some implementations. It may be implemented as a dedicated training device without also functioning as a base station. Accordingly, the base station 102b includes a DPD redetermination circuit that includes a down-converter 120 to frequency shift incoming RF signals to baseband, an analog-to-digital converter (ADC) 122 to digitize the baseband signals, and a digital signal processor (DSP) 124 to carry out the comparison of PA input to PA output signals and to determine the updated DPD parameters based on that comparison.

Each of the base stations 102 may include a controller 130 and one or more sensors 132. The one or more sensors 132 may monitor operating conditions at the base station, such as ambient temperature, power supply parameters, operating bandwidth, and the like. The controller 130 may receive signals from the one or more sensors 132 indicating the measured condition. For example, the signal may indicate the measured temperature or the measured power supply voltage. The controller 130 may determine whether the measured condition exceeds a threshold value. The threshold value may be set based on one or more initial measurements of the operating conditions taken when the DPD parameters were last updated. The threshold value may be expressed as a percentage change in those measured parameters, such as 5%, 10%, 20%, etc., and/or may be expressed in absolute terms as a particular value set based on the initial measurement.

If the measured parameter has changed by more than the threshold value or percentage, then the controller 130 sends a DPD update request message to the training device, i.e. a request for distortion model update. In response to the DPD update request message, the training device may determine a priority for the request and may schedule a time or instant at which the requesting base station may initiate transmission of its power amplifier input signal (PA input signal) and power amplifier output signal (PA output signal). The PA output signal is the RF signal output from the PA 112. The PA input signal is the analog RF signal input to the PA 112 from the up-converter 110. In some implementations, the PA input signal transmitted to the training device may be the analog signal prior to up-conversion.

The training device receives the PA input and PA output signals over a window of time and, using the feedback circuit including the DSP 124, it determines from a comparison of those signals an updated set of DPD parameters for the requesting base station 102. It then transmits those update DPD parameters to the base station 102 so it can update its DPD model 106 to account for the change in operating conditions.

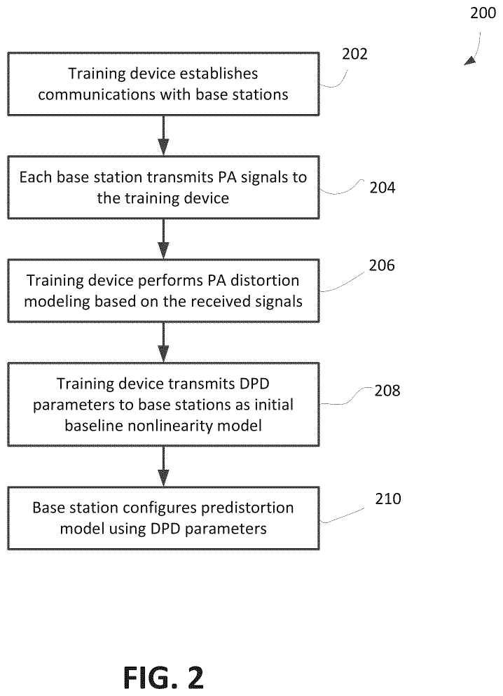

Reference is now made to FIG. 2, which shows, in flowchart form, one simplified example method 200 for initial configuration of base stations in a mobile communications network. The network includes a plurality of base stations and at least one training device. The training device may be one of the base stations in some implementations. Each base station includes a DPD model for applying pre-distortion to input signals prior to amplification and transmission. The DPD model is initially inactive when first deployed. Method 200 relates to initial configuration of the DPD model.

In operation 202, the training device and base stations are deployed and communications connections are established between the training device and the base stations. In some implementations, the communications connections are established over fronthaul and/or backhaul links. In establishing links with the base stations, the training device may determine which of the base stations (which may be all base stations in some cases) need initial DPD parameter determinations. It then schedules timeslots or windows within which to receive PA data from the base stations. That is, dependent on the availability of the communications links and the workload of the training device, it sends each base station a respective time or time window within which the base station can send the training device PA signals.

In operation 204, the base stations each, in their respective time windows, transmit PA input and PA output signals to the training device. These signals may be sent together with one or more of the operating condition measurements in some implementations so that the training device has a record of the operating conditions under which the DPD parameters are to be determined. The base stations may each record the local operating condition measurements at the time of sending PA signals so that they have a record of the operating condition measurements at the time of DPD parameter determination.

The training device, in each time window, receives PA input and PA output signals from one of the base stations and processes them to determined DPD parameters designed to create pre-distortion that will offset the non-linear distortion introduced into the signal by the PA, as indicated by operation 206. It then, in operation 208, transmits the determined DPD parameters to the base station. The base station then updates its DPD model using the determined DPD parameters received from the training device in order to configure it to apply pre-distortion to the baseband signal. In this manner, the base stations offload their initial pre-distortion configuration to the training device.

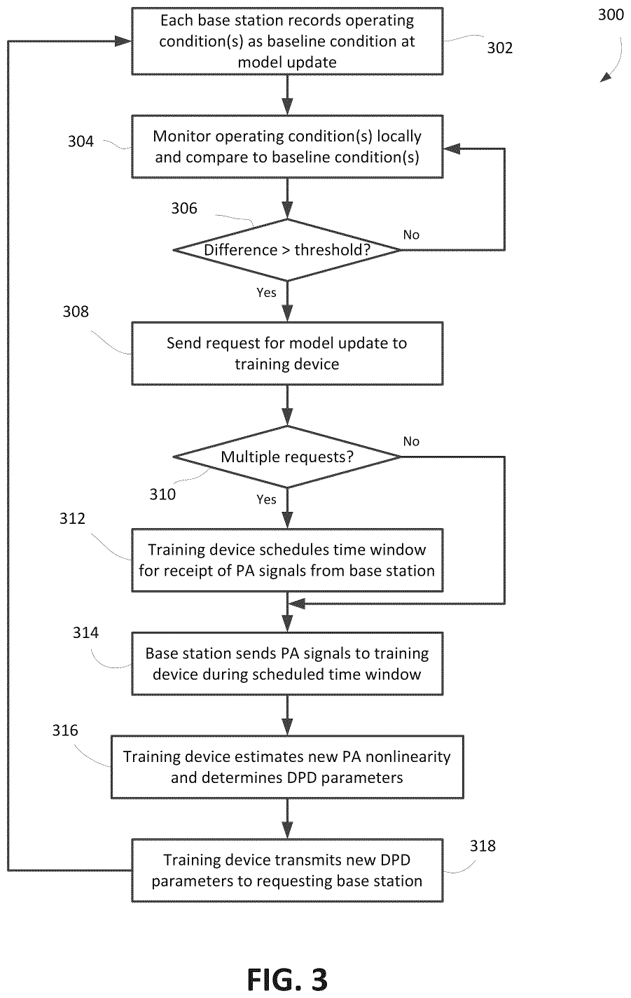

Reference is now made to FIG. 3, which shows, in flowchart form, a simplified example method 300 for updating pre-distortion values in a base station using a training device. The method 300 includes each base stations recording, in memory, one or more of the measured operating conditions at the time its initial or updated DPD parameters are determined, as indicated by operation 302. In operation 304, the base station continues monitoring its operating conditions while performing normal transmission and reception operations. It compares the ongoing or periodic operating condition measurements with its stored baseline value established in operation 302. As indicated by operation 304, if it detects a greater-than-threshold change in the operating condition then it initiates a DPD parameter update process; otherwise, it continues to monitor conditions in operation 306. As an example, the base station may monitor ambient temperature and may determine whether the ambient temperature has changed by more than a threshold amount, e.g. a set value or set percentage, from the recorded baseline temperature.

In some cases, although not show in FIG. 3, the base station may be configured to request DPD parameter redetermination after a certain period of time, irrespective of whether the operating conditions have changed. The time-based redetermination may result in the training device determining substantially the same DPD parameters. In some cases, if the redetermined DPD parameters have not changed by more than a threshold amount then the training device and/or base station may not update the DPD model.

If the operating condition triggers the DPD update process, then in operation 308 the base station transmits a message or notification to the training device to request a DPD parameter redetermination. In some cases, the message or notification may include the operating condition measurement and/or the operating condition baseline measurement. In some cases, the message or notification may indicate the degree or extent of variation in the measured operating condition from the recorded baseline operating condition.

The training device receives the message or notification from the base stations and, as indicated by operation 310, it may have received more than one such DPD update request from other base stations. In some cases, the training device may be actively engaged in a DPD update analysis for another base station. In some cases, it has received one or more other requests and has scheduled DPD updates for one or more other base stations. In some cases, the training device may receive data regarding the bandwidth availability and/or congestion status of communications links over which the base stations communicate with the training device.

If multiple competing DPD update requests have been received, then in operation 312 the training device schedules a time or time window within which each base station is to send PA data for its DPD update analysis. In some cases, the scheduling may take into account the operating conditions that triggered an update at each respective base station. Certain operating conditions may be designated as high priority than others. Certain base stations may be designated as higher priority that others. For example, a macro-call BS may be higher priority than a micro-cell BS or pico-cell BS. In some implementations, the severity or degree of change from the baseline condition may be the basis for determining priority. That is, if one base station's operating condition has varied from baseline by 25% and another base station's operating has varied from its baseline by 20%, the base station with the greater relative variation may have higher priority. In some cases, the absolute value of the variation may be the basis for determining priority.

In operation 314, the base station sends, at its designated time or time slot, PA input signals and PA output signals. By streaming the PA output signal to the training device in analog form, the training device is able to conduct waveform analysis with sufficient resolution to capture substantially all non-linearities across the operating bandwidth in its determination of DPD parameters. That analysis is carried out in operation 316, and the training device transmits the updated DPD parameters to the base station in operation 318 to enable the base station to update its DPD model.

In some embodiments, the network of base stations may include more than one training device. The training devices may be implemented within base stations in some cases or as edge devices or as other computing devices within the network. While in some embodiments, each base station may be assigned to a designated training device, such that each training device serves a respective subset of the base stations, in some cases one of the training devices is designated as a master or main training device and one or more other training devices are subsidiary training devices. The main training device may take the lead role in receiving DPD update requests and in scheduling of DPD updates by it and the subsidiary training devices. In other words, it allocates requests to the various training devices in order to manage load and distribute the computing workload and bandwidth usage across the network of training devices.

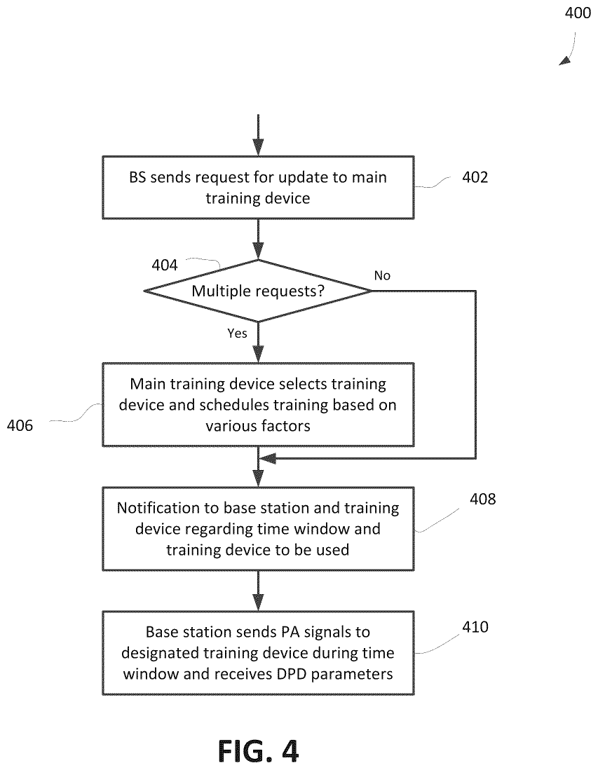

Reference is now made to FIG. 4, which shows, in flowchart form, one simplified example method 400 for updating DPD parameters for a plurality of base stations using two or more training devices. In this method 400 it is presumed that the base stations have been initialized and are operating using respective current sets of DPD parameters for performing digital predistortion, and that each of them is monitoring one or more operating conditions in order to determine whether to request an update to their respective DPD parameters. As indicated by operation 402, a request message or notification may be received by the main training device from one of the base stations. The request message or notification may include a base station identifier and data regarding the operating condition that triggered the request. The data may include data regarding the severity of the request, such as the type of operating condition and the degree to which its current measurement differs from the stored value that operating condition when the DPD parameters were last determined for that base station.

As shown in operation 404, if more than one DPD update request message has been received from the base stations, then the main training device determines which training device should handle the new request and when. The selection of a training device and the scheduling of the training operation may take into account a number of factors. For instance, the main training device may assess the computational load on each of the training devices. It may also take into account network congestion data with respect to links between the base station and the various training devices. For example, a first training device may be unoccupied but there may be too much network congestion on the links between the first training device and the base station to utilize the first training device. In addition to computation load and network congestion, the main training device may take into account severity of the operating condition and capability of DPD parameter determination at the local base station. This last factor assesses whether the requesting base station has the hardware capability to carry out the analysis locally and, if so, and if available training devices are limited in capacity, then the main training device may instruct the base station to do its own DPD update. However, if there is sufficient capacity available in one or more of the training devices, it may schedule the DPD update to be handled by a particular one of the training devices as a scheduled instant or time window.

As indicated by operation 408, the main training device sends a communication to the base station and a communication to the selected training device providing details of the scheduled training. The communication may identify the training device and/or the base station using unique identifiers (e.g. an IP address, a MAC address, another network routing address) and/or may provide the schedule time or time window for the training. At that time, the base station transmits its PA signals to the training device, as indicated by operation 410, and receives, in response, updated DPD parameters.

In yet another embodiment, the training device may decompose the computation-intensive training task into multiple sub-tasks, which can be accomplished by multiple training devices and/or base stations with processing capabilities. This decomposition may be achieved by segmenting the PA data into different pieces for distributed learning at different locations. The task assignment may be achieved by considering different factors, including but not limited to the geographical location, processing power, and communication resources availability. For example, part of the PA data may be processed in the local base station while the rest of the PA data may be processed in a training device. The allocation of tasks may be selected to ensure that the computational burden on each of the two devices stays within prescribed limitations. If each of the two or more devices performing a portion of the analysis produces a respective PA distortion model, then the overall distortion model may be obtained through combining the respective models, such as by taking a weighted average to obtain the final PA distortion model, which can be used to extract the updated DPD parameters for the local base station.

In yet another embodiment, one or more of the training devices may be configured to carry out a long-term analysis of the PA distortion model. After a series of PA model updates in the training device for one or more of the base stations, the training device may conduct a long-term distortion analysis based on the historical data from the base stations and the DPD parameters extracted. The long-term analysis may support PA variation analysis and support knowledge sharing.

The PA distortion may be modeled in a decomposed way, i.e. with multiple terms each corresponding to one of the operating conditions. a baseline model is trained in a similar way compared to the previous embodiments. Then, a modular structure may be developed by adding additional terms into the baseline model if operational condition variations are detected and DPD models are updated. In this modular model, each module corresponds to a distinct operating condition factor. For instance, separate modules may be dedicated to temperature variations and power fluctuation.

In some cases, the training device may receive operating condition data reports from the base stations. In some cases, the data may be sent regularly and periodically. In some cases, the data is sent only when a change in the operating condition is detected. In some cases, the data is sent only when the change is greater than a minimum threshold value, where the minimum threshold value is much lower than the threshold value for triggering a DPD update request. In some cases, the data is only sent when the change is significant enough to trigger a DPD update request.

Utilizing the operating condition data, the training device may conduct a long-term analysis of the PA behavior, including the exploration of the effects of various operational conditions on PA distortion characteristics over time. The modular nature of the model facilitates this process, as each operational condition can be individually analyzed and correlated with PA performance to the extent that the training device receives PA signal data correlated to the operating condition values. Leveraging the insights gained from long-term analysis across multiple base stations, the training device may develop predictive models. These models may be configured to anticipate the distortion characteristics of PAs based on the current operational conditions. For example, if a certain combination of temperature and power level tends to lead to a specific distortion pattern, the model may predict this behavior, allowing proactive adjustments for the DPD parameter generation. In some implementations, the predictive model may be used to determine and send a DPD parameter update before any current signal analysis is carried out by the training device. In some implementations, the predictive model may be used in place of actual determination of updated DPD parameters using PA signals, particularly in cases where the computational load and/or network congestion prevents a timely DPD parameter update analysis at a training device. In some cases, the predictive model may be used to determine updated DPD parameters temporarily until a training device is available and scheduled to carry out a PA signal analysis to determined updated DPD parameters empirically.

One aspect of some of these embodiments is a modular knowledge-sharing mechanism. For example, insights derived with regard to one PA operating under certain conditions can be applied to other PAs experiencing similar conditions. This sharing of modular knowledge derived from different power amplifiers and different base stations significantly enhances the efficiency of DPD applications across the network, as it allows for rapid and precise adjustments tailored to specific operational scenarios. Additionally, the multi-factor model is designed to be adaptive. As new data is continually fed into the system, the model refines its predictions and updates its modules. This continuous learning process ensures that the predictive models stay relevant and accurate, even as network conditions evolve over time.

As noted above, the behaviour of the PA is influenced by various operating conditions, including changes in environment, operating bandwidths, voltages, and manufacturing defects. With time-varying environments and multi-faceted external impacts, it may be advantageous to obtain numerous independent MP models for different scenarios. Therefore, it may be beneficial to represent the nonlinearities arising from these diverse operating conditions by training a comprehensive PA model instead of a series of independent and scenario-specific PA models. Based on this observation, in some example implementations, a multi-factor, memory polynomial (MFMP) PA nonlinearity model may be used. In one example, this model may be expressed as:

$${y}_{i} ( n ) = ( 1 - L ) {\underbrace{{\sum }_{p = 1}^{P} {\sum }_{m = 0}^{M} {a}_{0 pm} {x}_{i} ( n - m ) {\vert {x}_{i} ( n - m ) \vert}^{p - 1}}}_{Static inherent nonlinearity} + {Ω}_{i} {\underbrace{{\sum }_{l = 1}^{L} {\sum }_{p = 1}^{P} {\sum }_{m = 0}^{M} {a}_{lpm} {x}_{i} ( n - j ) {\vert {x}_{i} ( n - m ) \vert}^{p - 1}}}_{Dynamic condition - dependent nonlinearity} \qquad ( Eq . 1 )$$

The above expression reflects a combination of the static inherent nonlinearity and multiple condition-based dynamic nonlinearities that impact the PA behavior. A total number of L conditions are considered. Coefficient aₗₚₘ stands for the coefficient for the l-th condition. Moreover, the static nonlinearity is extracted L times to avoid repetitive modeling. In the above expression, xᵢ is the PA input signal and yᵢ is the PA output signal. The parameter P relates to the polynomial order and the parameter M is the memory depth. Therefore, a comprehensive PA behavioral model is obtained by considering and decomposing the impact of different conditions.

The involvement of MFMP could be highly complex with the growing number of base stations, operating conditions, polynomial orders, and memory depths. This exponentially increased complexity can make it inefficient for real-time model updates, which can be compute-intensive given the large MFMP coefficient matrix. To alleviate this issue, in some embodiments a control vector Ω_i may be designed for each PA, where the control vector may be given by:

$${Ω}_{i} = [ {w}_{i , 1} , ... , {w}_{i , L} ]$$

where w_{i,L} is a weighting factor used to indicate which memory polynomial should be used for the operating conditions. In some cases, the weighting factors may be binary, i.e. 0 or 1. As a result, by only extracting the specific value for the current situation, the entire MFMP construction can be simplified with reduced computational complexity.

To effectively establish the MFMP model to support efficient DPD in large-scale communication systems, a complexity-reduced PA distortion estimation method may be employed, such as one of the methods described above. That is, instead of conducting concurrent PA model training in each local BS, a training device with sufficient computation capability may be used to model and update the MFMP model for multiple distributed BSs. As a result, by offloading training tasks to the training device, the computation burden posed to distributed BSs is significantly reduced.

As described above, to capture the nonlinearity of each PA, the training device starts the initial model training by coordinating the communication for each BS. Depending on the availability, different communication methods, e.g., fiber optical cable, may be selected. Meanwhile, it may also schedule the transmission instant tⱼ for data about the j-th PA to avoid conflict. At the occurrence of transmission instant tⱼ, the BS with the j-th PA starts to transmit its local information [symbol] ={ [symbol] , [symbol] , [symbol] ₀} to the training device, where [symbol] and [symbol] are the input and output waveform data of PA j under its initial operating condition [symbol] ₀, respectively. Therefore, an initial PA model can be established according to (Eq. 1) as:

$${P}_{j , out} = {f}_{s} ( {P}_{j , in} , {C}_{j , 0} )$$

where ƒₛ(·) indicates the initial PA model obtained that will be regarded as the static inherent nonlinearity term in (Eq. 1). The obtained model parameters aₚₘ contained in ƒₛ will be transmitted back to each BS to linearize the local PA distortion with a DPD model established by taking the inverse of the MP coefficients. Therefore, with the offloading of concurrent PA estimation tasks from distributed small BSs to the centralized training device, the overall DPD process can be scheduled and optimized, which eliminates the overburden of local BSs with simplified network operations.

Due to the slowly varying nature of PA distortion and dynamic operating conditions, the initially estimated distortion model will become increasingly inaccurate over time. To avoid resource wasting inherent to unnecessary PA information transmission and distortion re-estimation, an efficient PA update mechanism is designed with the collaboration of lightweight onsite analysis on BSs and the scheduling at the training device.

Specifically, under time-varying operating conditions, BS j will only need to continuously monitor the current operating condition [symbol] and compare it with the inherent operating condition [symbol] ₀ recorded during initial training. After observing a noticeable variation, i.e., | [symbol] − [symbol] |>ξ^{l}, where ξ^{l} is a threshold value corresponding to the l-th operating condition, the BS will send a request to the training device for the model update. Once received the request from PA j, it will determine the preference of re-estimating the PA model under current operating conditions based on its previous knowledge and current workload, defined by a binary indicator δₗ as:

$${δ}_{l} = \{ \begin{matrix}0 , & if known {𝒞}_{j} with {ℒ}_{TD} > {\hat{ℒ}}_{TD} \\ 1 , & otherwise\end{matrix} ,$$

where [symbol] is its current workload preferred to be lower than a threshold [symbol] . With δᵢ=0, i.e., known operating condition with an unacceptable workload at the training device, the previous model obtained under [symbol] will be transmitted to the BS for model updates. Otherwise, it will schedule the transmission from the requested BS for updating the information of PA j as Îⱼ={ [symbol] ᵢₙ, [symbol] ₒᵤₜ, [symbol] }, based on which an updated model ƒₛ( [symbol] ᵢₙ, [symbol] ) can be re-estimated. Therefore, the dynamic nonlinearity term corresponding to the current l-th operating condition can be obtained as:

$${\hat{f}}_{l} ( {𝒫}_{j , in} , {𝒞}_{j}^{l} ) = {\hat{f}}_{s} ( {𝒫}_{j , in} , {𝒞}_{j}^{l} ) - {f}_{s} ( {𝒫}_{j , in} , {𝒞}_{0} )$$

Depending on the scheduling, previous or updated dynamic terms may be transmitted to the corresponding BS to update the MFMP model, which can be reorganized as

$${𝒫}_{j , out} = {\underbrace{{f}_{s} ( {𝒫}_{j , in} , {𝒞}_{j , 0} )}}_{inherent} + {\underbrace{{\sum }_{l = 1}^{L} ( 1 - {δ}_{l} ) {f}_{l} ( {𝒫}_{j , in} , {𝒞}_{j}^{l} )}}_{previous model} + {\underbrace{{\sum }_{l = 1}^{L} {δ}_{l} {\hat{f}}_{l} ( {𝒫}_{j , in} , {𝒞}_{j}^{l} )}}_{update model}$$

The decomposition of the overall PA nonlinearity into multiple condition-dependent terms helps update the complex PA model more efficiently. The controlled data transmission enabled by onsite lightweight analysis can further significantly reduce the occupation of bandwidth during PA model updates.

The static nonlinearity term, which is a dominant contributor to the overall PA nonlinearity, may also vary slowly over time. As a result, by comparing the previous and updated dynamic terms obtained under the same operating conditions, any varied static nonlinearity term that needs an update can be identified. In other words, if the current dynamic model \hat{ƒ}ₗ( [symbol] ᵢₙ, [symbol] ) varied from the previous model ƒₗ( [symbol] ᵢₙ, [symbol] ) obtained under the same situation, it will indicate a variation of the inherent nonlinearity term, given by:

$${𝒜}_{j}^{l} = \{ \begin{matrix}0 , & if j ∈ \{ ‖ {f}_{l} ( {𝒫}_{j , in} , {𝒞}_{j}^{l} ) - {\hat{f}}_{l} ( {𝒫}_{j , in} , {𝒞}_{j}^{l} ) ‖ \leq v \} \\ 1 , & otherwise\end{matrix}$$

where v is the variation threshold defined by the training device based on application requirements. The binary variable [symbol] =1 indicates outdated inherent terms found in the j-th PA, where the inherent operating condition should also be updated, i.e., [symbol] ₀= [symbol] , ∀ [symbol] =1 for further analysis.

As also noted above, the training device may record historical waveform data and operating conditions across some or all of the PAs, from which it can extract valuable knowledge to guide the update process. In one example, for each PA, the varying rate of both the inherent and dynamic terms can be estimated by adopting various time-series forecasting techniques, e.g., moving average. Based on the predicted update instants, in some embodiments the training device can intelligently schedule updates and ask the corresponding BS to transmit the PA information without receiving any update requests. As a direct result, the DPD update process can be automatically scheduled with simplicity during network operation.

In another aspect, the joint analysis of information from multiple BSs can help to explore the similarity among distributed PAs. After conducting proper data pre-processing techniques, the model coefficients obtained from different PAs can be grouped with the coordination of the training device. By transferring PA models within a group of similar PAs, resources used for PA

$${\hat{𝒫}}_{j , out} = {f}_{s , i} ( {𝒫}_{j , in} ) + {\sum }_{l = 1}^{L} {f}_{l , i} ( {𝒫}_{j , in} )$$

distortion estimation and update can be significantly reduced. To utilize the previous model ƒᵢ obtained at PA i, the input of another PA j should be fed into the model to obtain an estimated PA output [symbol] ₒᵤₜ, given by

The intrinsic difference among PAs, including the condition-dependent nonlinearity, will result in discrepancies between the transferred model and the actual behavior of PA j. To avoid performance degradation, the transferred model should be fine-tuned in each PA, while the tuning factor may, for example, be given by:

$${θ}_{j}^{*} = arg {min}_{{θ}_{j}} \frac{1}{N} {\sum }_{n = 1}^{N} ℒ ( {𝒫}_{j , out} ( n ) , {\hat{𝒫}}_{j , out} ( n ) , {θ}_{j} ) )$$

where N is the total number of samples from PA j, while [symbol] (·) represents the loss function to be minimized by adjusting the model parameter θⱼ. Once the updated model parameters θⱼ* are obtained through fine-tuning, they can be used to adjust the model in PA j. Additionally, these updated parameters will also be transmitted to the training device, allowing for further refinement of the transferred model. This model knowledge sharing can eliminate resource wasting for similar PAs by avoiding redundant estimation in complex networks.

### EXPERIMENTAL EVALUATION

In order to model the above-described systems and process in potential 5G/6G heterogeneous networks, it may be presumed that a macro-cell BS has sufficient processing power as the training device to handle all PA distortion estimation tasks. Different PA-specific conditions, including mismatch, temperature, and voltage, may be randomly assigned to different PAs. To assess the PA distortion estimation accuracy, normalized mean squared error (NMSE) may be employed to measure the difference between the actual PA output signals and prediction generated from the proposed method. The error may be defined as:

$${ϵ}_{ij} = \frac{{\sum }_{n = 1}^{N} {‖ {𝒫}_{j , out} ( n ) - {\hat{𝒫}}_{i , out} ( n ) ‖}^{2}}{{\sum }_{n = 1}^{N} {‖ {𝒫}_{j , out} ( n ) ‖}^{2}}$$

where [symbol] ₒᵤₜ(n) represents the actual PA output signal from the j-th PA, and [symbol] ₒᵤₜ(n) represents the PA output signal generated from the MFMP trained based on the i-th PA and transferred to other similar PAs. Moreover, without losing generality, four different PA scenarios may be considered, namely, the original PA A used for distortion estimation, PA B in the same BS as A with similar operating conditions, PA C in the same BS A with different operating conditions, and PA D in a different BS.

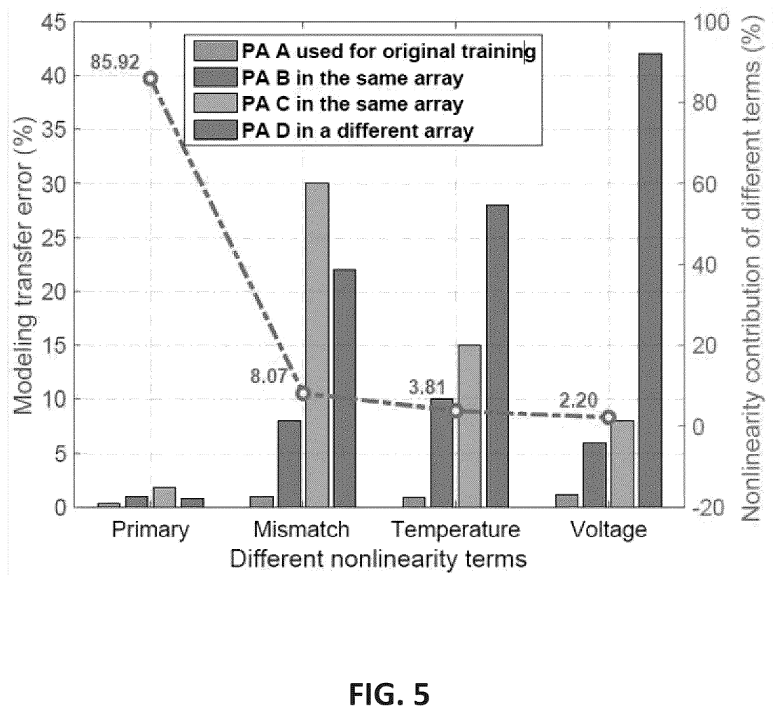

The model transferring error in terms of NMSE achieved by the proposed MFMP model is shown in FIG. 5, where it can be observed that an accurate initial training for PA A can be achieved with more than 99% accuracy. By transferring the initial model to other PAs, accurate results are expected, especially for the inherent nonlinearity term. For PAs with similar operating conditions, accurate results can be observed, indicating the effectiveness of the knowledge transfer approach in achieving accurate PA estimation across different base stations with similar PAs. However, for PA D installed in different operating conditions, due to the varied operating conditions, the training result will be degraded, indicating the necessity of model updates in the training device.

Furthermore, it will be observed that the proposed MFMP model can capture the inherent PA nonlinearity accurately, which accounts for more than 85% in the overall feature. Meanwhile, other condition-based terms, including mismatch, temperature, and voltage, will affect the PA nonlinearity much more slightly. As a result, by focusing on the inherent nonlinearity term, which is also modeled with the highest accuracy, a near-optimal performance of the PA can be guaranteed. The linearization of other condition-based terms can be flexibly achieved corresponding to the specific application requirement in terms of the desired PA distortion linearization accuracy.

To evaluate the estimation efficiency of the proposed PA estimation scheme, a modeling workload factor η, which jointly considers the bandwidth and computational resource consumption during its distortion estimation, given by

$${η}_{i} = {α}_{i} {P}_{i , C} / {\hat{P}}_{i} + {β}_{i} {B}_{i , C} / {\hat{B}}_{i}$$

where P_{i,C} and B_{i,C} are the consumed processing power and bandwidth for estimating the i-th PA distortion while \hat{P}ᵢ and \hat{B}ᵢ indicate the available resources. αᵢ and βᵢ are weighting factors according to the capability of the BS. A higher η will indicate a higher workload and a less efficient PA modeling process. With a full workload, i.e., η=1, the PA cannot be further modeled as all resources are consumed.

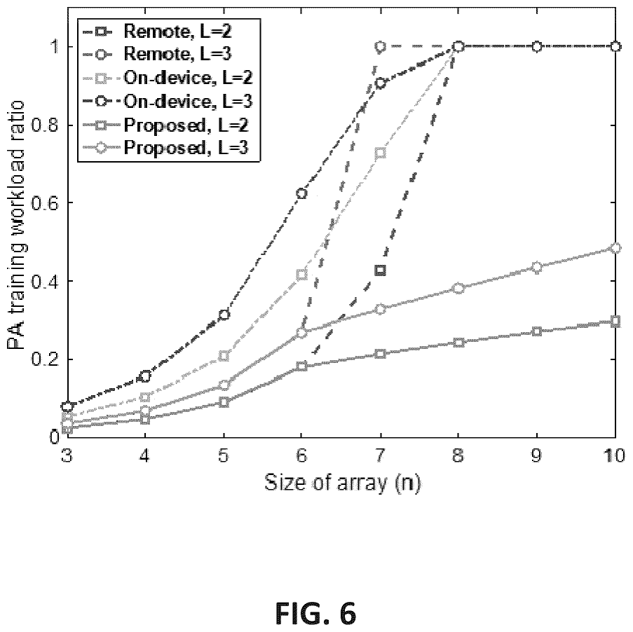

FIG. 6 shows three specific training approaches, including remote, on-device, and the proposed interactive offloading approach. Moreover, two scenarios are considered with different numbers of operating conditions, i.e., L=2 and L=3. It can be observed that the proposed method achieves the lowest workload ratio among the three schemes considering different operating conditions.

Moreover, the performance of these three training scenarios is also compared with larger antenna arrays. It can be observed from FIG. 6 that the benefit of the proposed method becomes more obvious with larger systems. This is because the proposed method will transfer the knowledge obtained among multiple PAs, avoiding resource wastage for redundant training. By contrast, the PA modeling for the other two scenarios becomes infeasible with larger sizes of arrays due to the exponentially increased resource consumption.

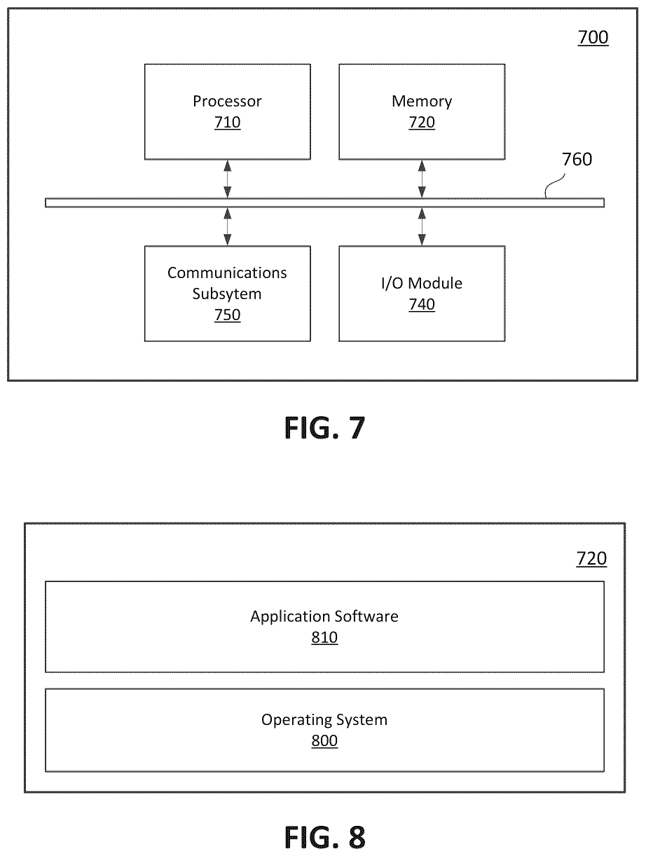

Reference will now be made to FIG. 7, which is a high-level diagram of an example computing device 700. The example computing device 700 includes a variety of modules. For example, the example computing device 700 may include a processor 710, a memory 720, an I/O module 740, and a communications subsystem 750. As illustrated, the foregoing example modules of the example computing device 700 are in communication over a bus 760.

The processor 710 is a hardware processor. The processor 710 may, for example, be one or more ARM, Intel x86, PowerPC processors, or the like.

The memory 720 allows data to be stored and retrieved. The memory 720 may include, for example, random access memory, read-only memory, and persistent storage. Persistent storage may be, for example, flash memory, a solid-state drive or the like. Read-only memory and persistent storage are a computer-readable medium. A computer-readable medium may be organized using a file system such as may be administered by an operating system governing overall operation of the example computing device 700.

The I/O module 740 allows the example computing device 700 to receive input signals and to transmit output signal. Input signals may, for example, correspond to input received from a user. Some output signals may, for example, allow provision of output to a user. The I/O module 740 may serve to interconnect the example computing device 700 with one or more input devices. Input devices may, for example, include one or more of a touchscreen input, keyboard, or the like. The I/O module 740 may serve to interconnect the example computing device 700 with one or more output devices. Output devices may include, for example, a display screen such as, for example, a liquid crystal display (LCD), a touchscreen display. Additionally, or alternatively, output devices may include devices other than screens such as, for example, a speaker, indicator lamps (such as, for example, light-emitting diodes (LEDs)), and printers.

The communications subsystem 750 allows the example computing device 700 to communicate with other electronic devices and/or various communications networks using various networking protocols. The communications subsystem 750 may allow the example computing device 700 to send or receive communications signals. The communications may be digital, analog or both. Communications signals may be sent or received according to one or more protocols or according to one or more standards. For example, the communications subsystem 750 may allow the example computing device 700 to communicate via an optical network. In some embodiments, all or a portion of the communications subsystem 750 may be integrated into a component of the example computing device 700. In some examples, the communications module may be integrated into a communications chipset.

Software instructions are executed by the processor 710 from a computer-readable medium. For example, software may be loaded into random-access memory from persistent storage within memory 720. Additionally, or alternatively, instructions may be executed by the processor 710 directly from read-only memory of the memory 720.

FIG. 8 depicts a simplified organization of software components stored in memory 720 of the example computing device 700. As illustrated, these software components include, at least, application software 810 and an operating system 800.

The application software 810 adapts the example computing device 700, in combination with the operating system 800, to operate as a device performing a particular function. While a single application software 810 is illustrated in FIG. 8, in operation, the memory 820 may include more than one application software and different application software may perform different operations.

The operating system 800 is software. The operating system 800 allows the application software 810 to access the processor 710, the memory 720, the I/O module 740, and the communications subsystem 750. The operating system 800 may, for example, be iOS™, Android™, Linux™, Microsoft Windows™, or the like.

The application software 810 may, when executed, cause the processor 710 to carry out operations to implement at least some portion of one or more of the methods described herein. In some cases, the application software 810 may implement some or all of a DPD parameter update process and/or the modeling of PA distortion and/or the long-term analysis of PA distortion modeling to generate predictive PA models.

The various embodiments presented above are merely examples and are in no way meant to limit the scope of this application. Variations of the innovations described herein will be apparent to persons of ordinary skill in the art, such variations being within the intended scope of the present application. In particular, features from one or more of the above-described example embodiments may be selected to create alternative example embodiments including a sub-combination of features which may not be explicitly described above. In addition, features from one or more of the above-described example embodiments may be selected and combined to create alternative example embodiments including a combination of features which may not be explicitly described above. Features suitable for such combinations and sub-combinations would be readily apparent to persons skilled in the art upon review of the present application as a whole. The subject matter described herein and in the recited claims intends to cover and embrace all suitable changes in technology.

What is claimed is:

1. A computing device for use in a wireless network, the wireless network including a plurality of base stations, comprising:
a controller configured to receive a request for distortion model update from one of the base stations;
a communications subsystem configured to, in response to the request, send a message to the base station and to receive, during a time window, a power amplifier input signal and a power amplifier output signal from said one of the base stations; and
a digital signal processor to generate an updated set of parameters for a predistortion model using the power amplifier input signal and the power amplifier output signal,
wherein the communications subsystem is further configured to transmit the updated set of parameters to said one of the base stations in response to the request.

2. The computing device of claim 1, wherein the request for distortion model update includes data regarding an operating condition that triggered transmission of the request for distortion model update.

3. The computing device of claim 2, wherein the data regarding the operating condition includes a measurement at the base station of one of temperature, voltage, power, or operating bandwidth.

4. The computing device of claim 1, wherein the power amplifier output signal is an analog waveform.

5. The computing device of claim 4, wherein the analog waveform is an RF waveform at a transmission frequency.

6. The computing device of claim 1, wherein the message sent to the base station includes data specifying the time window, and wherein the time window begins at a future time.

7. The computing device of claim 2, wherein the controller is configured to determine the time window in part based upon whether other requests for distortion model update have been received from other base stations, computational workload at the computing device, or severity of the operating condition.

8. The computing device of claim 1, wherein the request for distortion model update, the message, the power amplifier input signal, and the power amplifier output signal are communicated over fronthaul or backhaul network links.

9. A base station for wireless communications, comprising:
an RF chain that receives an input signal and produces a power amplifier output signal to drive an antenna array, the RF chain including a predistortion model, a digital-to-analog converter, an up-converter, and a power amplifier;
a sensor monitoring an operating condition at the base station; and
a controller for receiving a signal from the sensor, wherein the controller is configured to:
in response to determining that the operating condition varies from a previously determined operating condition, transmit a request for distortion model update to a computing device;
receive a response and, based on the response, during a time window, transmit a power amplifier input signal and the power amplifier output signal to the computing device;
receive, from the computing device, an updated set of parameters for the predistortion model; and
update the predistortion model using the updated set of parameters.

10. The base station of claim 9, wherein the controller is configured to determine that the operating condition varies from a previously determined operating condition by determining that a value measured by the sensor differs from the previously determined operating condition by more than a threshold amount.

11. A method of adaptively updating a predistortion model for a power amplifier for a base station, the method including:
receiving at a remote computing device, from the base station, a request for distortion model update;
in response to the request, sending a message to the base station and receiving, during a time window, a power amplifier input signal and a power amplifier output signal from the base station;
generating an updated set of parameters for the predistortion model using the power amplifier input signal and the power amplifier output signal; and
transmitting the updated set of parameters for the predistortion model to the base station to be used in updating the predistortion model.

12. The method of claim 11, wherein receiving the request for distortion model update includes receiving data regarding an operating condition that triggered transmission of the request for distortion model update.

13. The method of claim 12, wherein the data regarding the operating condition includes a measurement at the base station of one of temperature, voltage, power, or operating bandwidth.

14. The method of claim 11, wherein the power amplifier output signal is an analog waveform.

15. The method of claim 14, wherein the analog waveform is an RF waveform at a transmission frequency.

16. The method of claim 11, wherein the message sent to the base station includes data specifying the time window, and wherein the time window begins at a future time.

17. The method of claim 12, further including determining the time window in part based upon whether other requests for distortion model update have been received from other base stations, computational workload at the computing device, or severity of the operating condition.

18. The method of claim 11, wherein the request for distortion model update, the message, the power amplifier input signal, and the power amplifier output signal are communicated over fronthaul or backhaul network links.

19. A method of adaptively updating a predistortion model for a power amplifier in a base station, the base station including an RF chain that receives an input signal and produces a power amplifier output signal to drive an antenna array, the RF chain including a predistortion model, a digital-to-analog converter, an up-converter, and a power amplifier, the method including:
monitoring an operating condition using a sensor;
in response to determining that the operating condition varies from a previously determined operating condition, transmitting a request for distortion model update to a computing device;
receive a response and, based on the response, during a time window, transmitting a power amplifier input signal and the power amplifier output signal to the computing device;
receiving, from the computing device, an updated set of parameters for the predistortion model; and
updating the predistortion model using the update set of parameters.

20. The method of claim 19, wherein determining that the operating condition varies from a previously determined operating condition includes determining that a value measured by the sensor differs from the previously determined operating condition by more than a threshold amount.
